(19) United States
(12) Patent Application Publication
(10) Pub. No.: US 2015/0189789 A1
(43) Pub. Date: Jul. 2, 2015

(54) HEAT RADIATION MEMBER FOR ELECTRONIC DEVICE

(71) Applicant: Samsung Display Co., Ltd., Yongin-City (KR)

(72) Inventor: Yeong-Sang Suh, Yongin-City (KR)

(73) Assignee: Samsung Display Co., Ltd., Yongin-City (KR)

(21) Appl. No.: 14/229,557

(22) Filed: Mar. 28, 2014

(30) Foreign Application Priority Data
Dec. 30, 2013 (KR) 10-2013-0166403

(51) Int. Cl. H05K 7/20

(52) U.S. Cl. CPC H05K 7/2039

(57) ABSTRACT

A heat radiation member for an electronic device includes: a housing comprising an internal cavity; graphite in the internal cavity; and one or more spring members in the internal cavity and overlapping the graphite.

### CROSS-REFERENCE TO RELATED APPLICATION

This application claims priority to and the benefit of Korean Patent Application No. 10-2013-0166403, filed on Dec. 30, 2013, in the Korean Intellectual Property Office, the entire content of which is incorporated herein by reference in its entirety.

### BACKGROUND

1. Field

Aspects of embodiments of the present invention relate to a heat radiation member for an electronic device.

2. Description of the Related Art

In general, electronic devices, such as computers, portable personal terminals (e.g., laptops, personal digital assistants (PDAs), smart phones, etc.), and various other communication devices generate a relatively high amount of heat during operation and charging/discharging due to the use of electricity, and the heat is accumulated in the electronic devices, which may degrade the functionality of the electronic devices or cause safety concerns. When the heat generated in electronic devices is not controlled, the lifespan of electronic devices may be decreased, or dangerous safety hazards such as explosions or fires may occur, thereby generating defects and erroneous operation of the electronic devices. Further, the heat may degrade the image definition and resolution of plasma display panels and various other display devices, such as liquid crystal display (LCD) monitors and light emitting diode (LED) monitors, for which consumer demand has recently increased, thereby degrading the reliability and stability of the products.

Accordingly, a heat radiation member may be included inside or outside electronic devices in order to control heat generated in the electronic devices. Heat radiation members, however, may have lower strength than that of the electronic device and insufficient heat conductivity, such that heat generated in the electronic device may not be efficiently discharged.

### SUMMARY

According to aspects of example embodiments of the present invention, a heat radiation member for an electronic device includes: a housing including an internal cavity; graphite in the internal cavity; and one or more spring members in the internal cavity and overlapping the graphite.

The housing may further include a pair of base units facing each other and spaced apart from each other.

The heat radiation member may further include one or more side units coupling edges of the base units.

The housing may further include one or more partition walls partitioning the internal cavity.

The one or more partition walls may partition the internal cavity into two or more spaces, and the graphite and the one or more spring members may be in the spaces.

The partition wall and the spring member may include a same material.

The partition wall may include one or more of copper and aluminum.

The partition wall may include a plate, and the plate may include one or more openings.

The spring member may be in contact with both of the base units.

The spring member may include one or more of copper and aluminum.

The graphite may include a powder graphite.

The heat radiation member may include an adhesion member at an external surface of the housing.

The adhesion member may include an adhesive contacting the housing and a sheet covering an external surface of the adhesive.

The housing may include a polymer material.

### BRIEF DESCRIPTION OF THE DRAWINGS

Aspects of example embodiments will now be described more fully hereinafter with reference to the accompanying drawings; however, they may be embodied in different forms and should not be construed as limited to the embodiments set forth herein. Rather, these embodiments are provided so that the present disclosure will be thorough and complete, and will more fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a perspective view of a heat radiation member for an electronic device according to an example embodiment of the present disclosure.

FIG. 2 is an exploded perspective view illustrating the heat radiation member for the electronic device of FIG. 1.

FIG. 3 is a cross-sectional view taken along the line I-I of FIG. 1.

FIG. 4A is a perspective view illustrating the spring member of FIG. 2.

FIG. 4B is a perspective view of a spring member according to another example embodiment of the present invention.

FIG. 5 is a view schematically illustrating an internal side of a housing according to another example embodiment of the present invention.

FIG. 6A is a perspective view illustrating the partition wall illustrated in FIG. 5.

FIG. 6B is a perspective view illustrating the partition wall according to another example embodiment of the present invention.

### DETAILED DESCRIPTION

Other details of the example embodiments are included in the detailed description and the drawings.

Various aspects and features of the present disclosure and methods accomplishing thereof will become more apparent from the following detailed description of example embodiments with reference to the accompanying drawings. However, the present invention is not limited to example embodiments disclosed below and may be implemented in various forms, and when one constituent element referred to as being “connected to” or “coupled to” another constituent element, one constituent element can be directly coupled to or connected to the other constituent element, but intervening elements may also be present. Further, some details of the present invention may be omitted to clarify the description of the present invention, and like reference numerals designate like elements throughout the specification.

Hereinafter, embodiments of the present invention will be described in some detail with reference to the accompanying drawings.

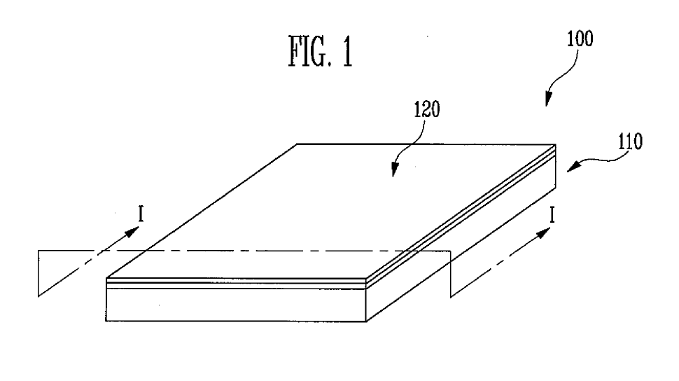

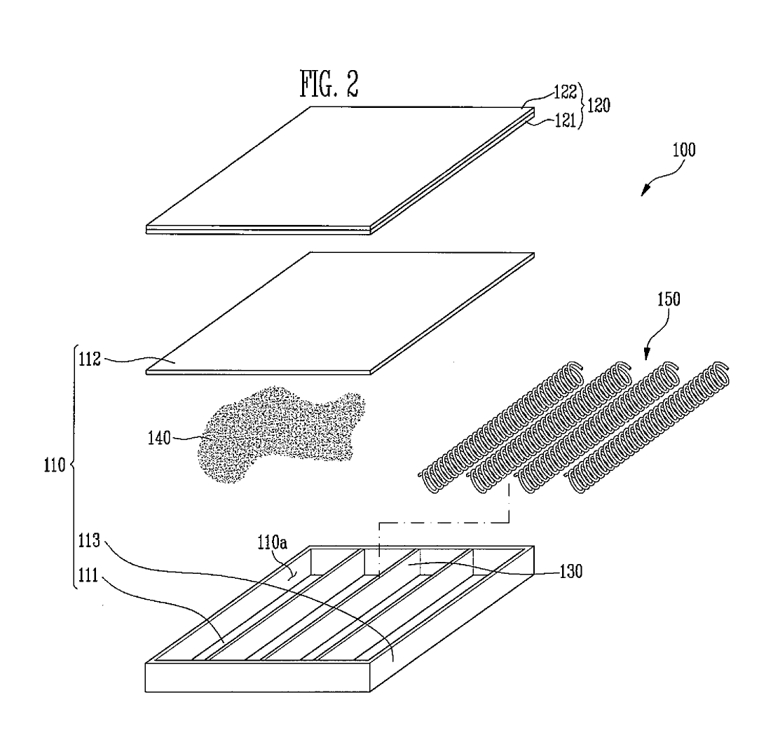

FIG. 1 is a perspective view of a heat radiation member for an electronic device according to an example embodiment of the present disclosure, and FIG. 2 is an exploded perspective view illustrating the heat radiation member for the electronic device of FIG. 1. FIG. 3 is a cross-sectional view taken along the line I-I of FIG. 1.

A heat radiation member 100 for an electronic device according to an example embodiment of the present disclosure includes a housing 110 including a space 110a inside therein, graphite 140 formed in the space 110a, and one or more spring members 150 formed in the space 110a and overlapping the graphite 140. Further, one or more adhesion members 120 may be further positioned on an external surface of the housing 110.

The adhesion member 120 may be positioned at the external surface of the housing 110 to fix or secure the heat radiation member 100 for the electronic device to the electronic device. The adhesion member 120 may include an adhesive provided on the housing 110 and a sheet 122 provided so as to cover the adhesion member 121 on an external surface of the adhesive 121. The sheet 122 may have a surface area that is equal to or larger than that of the adhesive 121, thereby preventing or reducing foreign substances or contaminants from being entering the adhesive 121, which may degrade adhesive force.

The housing 110 may be arranged in order to protect the graphite 140 and the spring member 140 included inside the housing 110. The housing may be formed of a nonconductor, such as a polymer material, and for example, polyimide (PI).

The housing 110 may include a pair of base units (or base plates) 111 and 112, which face each other (e.g., a bottom surface of the base unit 112 may face a top surface of the base unit 111) while being spaced apart from each other. The pair of base units 111 and 112 may be arranged to have corresponding sizes. Further, one or more partition walls 130 dividing the internal space of the housing 110 may be positioned between the pair of base units 111 and 112, and further, the housing 110 may include one or more side units 113 coupling edges of the pair of base units 111 and 112 with each other. The side units 113 are positioned in order to seal (or substantially seal) the internal side of the housing 110, and may be integrally formed with (e.g., molded or formed as a single continuous material) or separately manufactured from the pair of base units 111 and 112. The partition wall 130 and the side unit 113 may include both sides or any one side of the pair of base units 111 and 112, and hereinafter, the description will be given based on a case where the partition wall 130 and the side unit 130 are provided at any one side of the base unit 111.

In the heat radiation member 100 for the electronic device according to the present example embodiment, the housing 110 may be divided or partitioned into one or more spaces 110a therein, and the spaces 110a may be formed by the partition walls 130. One or more partition walls 130 may be positioned in parallel while being spaced apart from each other between one pair of base units 111 and 112, and the spaces 110a, which are spaced apart from each other, may be formed between the partition wall 130 and the side units 113, or the adjacent partition walls 130. For example, the partition walls 130 may be vertically coupled to one pair of base units 111 and 112.

Graphite generally has high heat conductivity properties, thereby being variously used as a material for discharging heat of electronic devices. For example, a thin heat radiation member may be used in a mobile product and the like, such that graphite is manufactured as a sheet-shaped heat radiation member and attached to the product for use. Because heat radiation members manufactured in a sheet shape may have relatively weak strength, the heat radiation member may be easily damaged when external force, such as impact or bending, is applied, such that the heat radiation function of the electronic device may be impeded, and further, when the heat radiation member is damaged, the heat radiation member may break into smaller particles due to the properties of graphite, thereby potentially contaminating the inside of the electronic device and degrading the function of the electronic device.

The heat radiation member for electronic devices according to the present example embodiment uses the graphite having relatively high heat conductivity, thereby improving strength of the heat radiation member for the electronic device. Accordingly, because the heat radiation member for electronic devices may not be easily damaged by external forces, particles of the graphite generated due to the damage may not be generated. Further, the heat radiation member for electronic devices according to the present example embodiment may further improve heat conductivity of the graphite, thereby further improving efficiency of heat radiation of the electronic device.

As described above, the partition walls 130 are provided inside the housing 110, and the partition walls 130 may divide the internal side (e.g., an internal cavity) of the housing 110 into one or more spaces 110a. The graphite 140 may be filled (e.g., deposited) inside the spaces 110a formed as described above together with one or more spring member 140.

For example, the partition wall 130 may be formed of one or more of copper and aluminum, which are conductive materials. The partition wall 130 is formed of a conductive material, such as copper or aluminum having excellent or high heat conductivity, thereby further improving heat conductivity together with graphite. The partition wall 130 may support one pair of base units 111 and 112 between one pair of base units 111 and 112, thereby further improving strength of the heat radiation 100 for the electronic device.

Further, the spring member 150 may be positioned in one or more of the spaces 110a. The spring member 150 may be positioned so as to be in contact with the pair of base units 111 and 112 facing each other. In this case, the spring member 150 may be positioned such that a maximum length S1 of a cross-section of the spring member 150 in a vertical direction relative to the pair of base units 111 and 112 corresponds to (e.g., is equal to) a height h of a space between the pair of base units 111 and 112. Accordingly, the spring members 150 may support the space between the one pair of base units 111 and 112, and may improve strength of the heat radiation member 100 for the electronic device together with the partition walls 130.

The graphite 140 may be provided in the form of a powder such that a density and an area of a surface of the graphite 140 are improved, thereby further improving heat conduction efficiency. The graphite 140 may be filled together with the spring members 150 to be in contact with the spring members 150.

For example, the spring member 150 may be formed of a suitable conductive (e.g., metal) material such as copper or aluminum, having excellent or high heat conductivity, thereby further improving heat conductivity between the graphite 140.

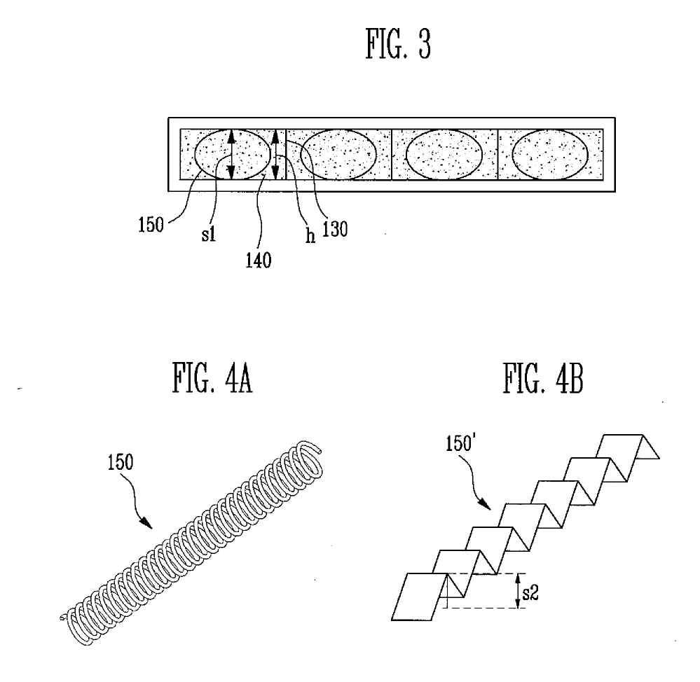

FIG. 4A is a perspective view illustrating the spring member of FIG. 2, and FIG. 4B is a perspective view of a spring member according to another example embodiment of the present invention.

Referring to FIGS. 4A and 4B, the spring members 150 and 150′ may be formed or positioned along a direction parallel to the partition wall 130 (see FIG. 2). For example, the spring members 150 and 150′ may be formed in a spiral shape of which a cross-section has a generally circular shape as illustrated in FIG. 4A, or may be formed in a zigzag shape of which a cross-section has a generally quadrangular shape as illustrated in FIG. 4B. The spring member 150′ as illustrated in FIG. 4B may be formed so that a vertical length S2 of the cross-section of the spring member 150′ corresponds (e.g., is approximately equal) to the height h of the spaced space between one pair of base units 111 and 112 (see FIG. 2) to support one pair of base units. Contents to be described below are related to the spring members 150 and 150′ illustrated in FIGS. 4A and 4B, so that the description will be given based on the spring member 150 illustrated in FIG. 4A for convenience of the description.

The spring 150 may be provided, for example, in a generally spiral or zigzag structure having a relatively large surface area so as to improve a surficial contact area with the graphite 140. The structure of the spring 150 may be in contact with the graphite 140 to fix (e.g., stabilize or secure) the graphite 140, and prevent or reduce the graphite 140 from being scattered, in order to maintain an existing filling density even when an external impact is applied. Accordingly, it may be possible to prevent or reduce contamination by the particles of the graphite 140 within the electronic device, and the existing filling density may be maintained even after an external impact is applied, thereby preventing or reducing deterioration of heat conduction performance. Further, the structure of the spring 150 according to the present example embodiment has elastic force, thereby preventing or reducing the heat radiation member 100 for the electronic device from being damaged by a buffer effect in a case where an external impact, such as fall, is applied to the heat radiation member 100 for the electronic device.

Further, the partition wall 130 and the spring member 150 may be formed of the same material. The partition wall 130 and the spring member 150 are formed of the same material, so that it may be possible to decrease a production cost and uniformly form heat conductivity in relation to the graphite 140, thereby further improving a heat conduction effect.

Further, the structure of the spring 150 may further include surface roughness on a surface of the spring 150. The surface roughness formed on the surface of the spring 150 may further improve frictional force with the graphite 140, so that it is possible to more effectively keep the graphite 140 within the spring 150, thereby maintaining the filling density of the graphite 140 without significant changes in the filling density even when an external force is applied.

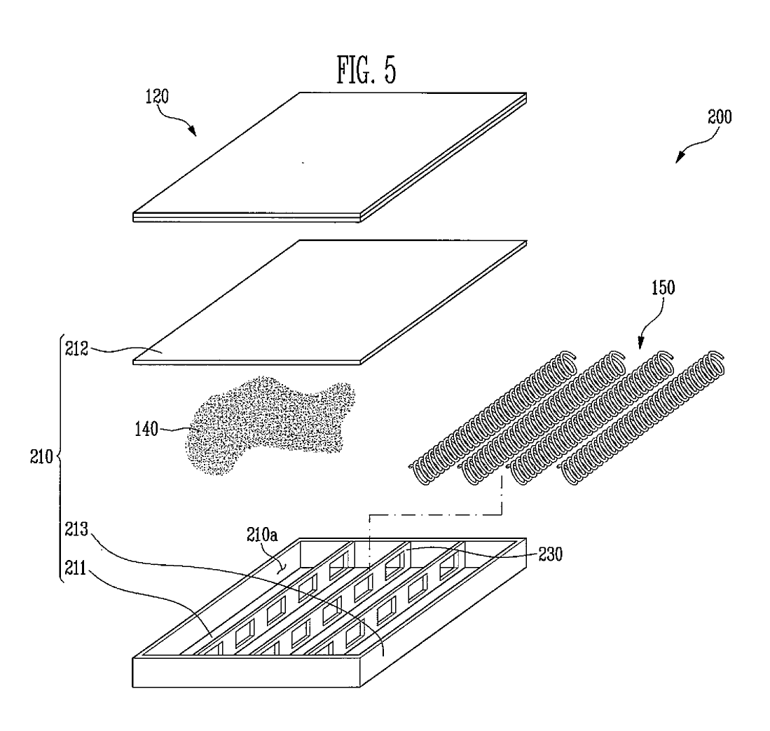

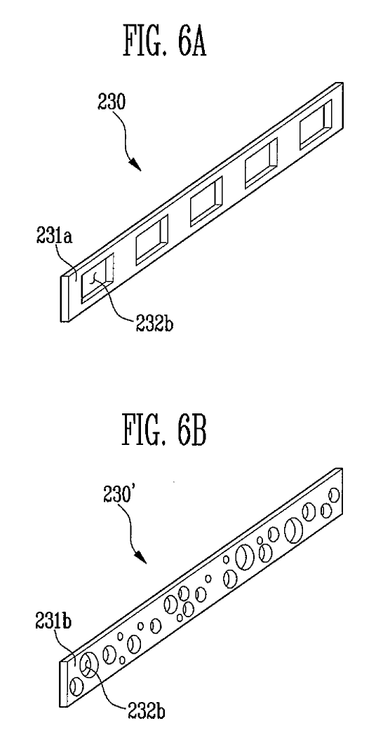

Hereinafter, another example embodiment of the present invention will be described with reference to FIGS. 5 to 6B. Except for the contents to be described below, contents of another example embodiment of the present invention described with reference to FIGS. 5 to 6B are similar to the contents of the example embodiment of the present invention described with reference to FIGS. 1 to 4B, thereby some repetitive detailed descriptions thereof will be omitted.

FIG. 5 is a view schematically illustrating an internal side (e.g., an internal cavity) of a housing according to another example embodiment of the present invention, and FIG. 6A is a perspective view illustrating a partition wall illustrated in FIG. 5.

A heat radiation member 200 for an electronic device according to the present example embodiment may include a housing 210 accommodating graphite 140 and a housing 210 therein, and the internal side of the housing 210 may be formed of a plurality of spaces 210a, partitioned by one or more partition walls 230. One or more spring members and the graphite may be filled in each of the spaces 210a formed by the partition walls 230. The housing 210 may include a pair of facing plates 211 and 222, and a side part (or side wall) 213 coupling edges of the pair of plates 211 and 212. Further, the heat radiation member 200 for the electronic device may include an adhesion member 120 on an external surface of the housing 210 so as to facilitate the heat radiation member 200 being fixed to an external device.

The partition wall 230 may include a plate 231a formed of a conductive material and one or more openings 232a provided inside the plate 231a. The partition walls 230 may include spaces 210a filled with the graphite 140. In this case, the plate 231a of the partition wall may reinforce strength of the housing 210, and the opening 232a is provided at the plate 232a, thereby lightening or reducing the weight of the heat radiation member 200 for the electronic device. Further, the graphite 140 may be in contact with the graphite 140 formed in the adjacent space 210a through the opening 232a. The graphite 140 is a material having very excellent heat conductivity, and may have a higher heat conductivity than that of the partition wall 230 formed of a conductive metal. Accordingly, the graphite 140 formed in the adjacent spaces 210a by the partition walls 230 may communicate with each other without being separated by the partition walls 230, thereby further improving efficiency of heat conduction of the heat radiation member 200 for the electronic device.

FIG. 6B is a perspective view illustrating a partition wall according to another example embodiment of the present invention.

Referring to FIG. 6B, a partition wall 230′ according to the present example embodiment may include a plate 231b and an opening 232b provided at the plate 231b. For example, the opening 232a may be formed in a quadrangular shape like the partition wall 230 illustrated in FIG. 6A, and further, the opening 232b may be formed in a circular shape having various shapes like the partition wall 230′ illustrated in FIG. 6A.

According to the example embodiments of the present invention, it may be possible to provide the heat radiation member for an electronic device with improved strength.

Further, according to example embodiments of the present invention, it may be possible to provide the heat radiation member for an electronic device of which physical strength and heat conductivity are improved by using a novel member.

Further, according to example embodiments of the present invention, it may be possible to provide the heat radiation member for an electronic device attached to an electronic device to efficiently discharge heat generated in the electronic device.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims, and their equivalents.

What is claimed is:

1. A heat radiation member for an electronic device, the heat radiation member comprising:
a housing comprising an internal cavity;
graphite in the internal cavity; and
one or more spring members in the internal cavity and overlapping the graphite.

2. The heat radiation member of claim 1, wherein the housing further comprises a pair of base units facing each other and spaced apart from each other.

3. The heat radiation member of claim 2, further comprising:
one or more side units coupling edges of the base units.

4. The heat radiation member of claim 1, wherein the housing further comprises one or more partition walls partitioning the internal cavity.

5. The heat radiation member of claim 4, wherein the one or more partition walls partition the internal cavity into two or more spaces, and wherein the graphite and the one or more spring members are in the spaces.

6. The heat radiation member of claim 4, wherein the partition wall and the spring member comprise a same material.

7. The heat radiation member of claim 4, wherein the partition wall comprises one or more of copper and aluminum.

8. The heat radiation member of claim 4, wherein the partition wall comprises a plate, wherein the plate comprises one or more openings.

9. The heat radiation member of claim 2, wherein the spring member is in contact with both of the base units.

10. The heat radiation member of claim 1, wherein the spring member comprises one or more of copper and aluminum.

11. The heat radiation member of claim 1, wherein the graphite comprises a powder graphite.

12. The heat radiation member of claim 1, further comprising an adhesion member at an external surface of the housing.

13. The heat radiation member of claim 12, wherein the adhesion member comprises an adhesive contacting the housing and a sheet covering an external surface of the adhesive.

14. The heat radiation member of claim 1, wherein the housing comprises a polymer material.
